(19) United States
(12) Patent Application Publication
(10) Pub. No.: US 2022/0406583 A1
(43) Pub. Date: Dec. 22, 2022

(54) DEPOSITION SYSTEM AND METHOD

(71) Applicant: Taiwan Semiconductor Manufacturing Co., Ltd., Hsinchu (TW)

(72) Inventors: Wen-Hao CHENG, Hsinchu (TW); Hsuan-Chih CHU, Hsinchu (TW); Yen-Yu CHEN, Hsinchu (TW)

(21) Appl. No.: 17/352,133

(22) Filed: Jun. 18, 2021

(51) Int. Cl. H01J 37/34; C23C 14/54; C23C 14/34

(52) U.S. Cl. CPC H01J 37/3476; H01J 37/3447; C23C 14/545; C23C 14/34; H01J 2237/332

(57) ABSTRACT

A deposition system is provided capable of controlling an amount of a target material deposited on a substrate and/or direction of the target material that is deposited on the substrate. The deposition system in accordance with the present disclosure includes a substrate process chamber. The deposition includes a substrate pedestal in the substrate process chamber, the substrate pedestal configured to support a substrate, a target enclosing the substrate process chamber, and a collimator having a plurality of hollow structures disposed between the target and the substrate, wherein a length of at least one of the plurality of hollow structures is adjustable.

### BACKGROUND

To produce semiconductor devices, a semiconductor substrate, such as a silicon wafer, which is a raw material for the semiconductor devices, must go through a sequence of complicated and precise process steps such as diffusion, ion implantation, chemical vapor deposition, photolithography, etch, physical vapor deposition, chemical mechanical polishing, and electrochemical plating.

The physical vapor deposition (PVD) is generally used to deposit one or more layers (e.g., thin film) on the semiconductor substrate. For example, sputtering, a form of the PVD, is commonly used in the semiconductor fabrication process to deposit complex alloys and metals, such as silver, copper, brass, titanium, titanium nitride, silicon, silicon nitride, and carbon nitride, on the substrate. The sputtering includes a target (source), and a substrate (e.g., wafer) positioned in parallel to each other in a vacuum enclosure (e.g., process chamber). The target (cathode) is electrically grounded while the substrate (anode) has positive potential. Argon gas, which is relatively heavy and is a chemically inert gas, is commonly used as the sputtering ion species in the sputtering process. When the argon gas is introduced into the chamber, a plurality of collisions occurs with electrons released from the cathode. This causes the argon gas to lose its outer electrons and become positively charged argon ions. The positively charged argon ions are strongly attracted to the negative potential of the cathode target. When the positively charged argon ions strike the target surface, the momentum of the positively charged argon ions transfers to the target material to dislodge one or more atoms which eventually deposit on the substrate.

The target material atoms exiting the target are deposited on the substrate along various traveling paths.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view of a substrate process chamber in a deposition system according to one or more embodiments in the present disclosure.

FIG. 2 is a top view of an adaptable collimator according to one or more embodiments in the present disclosure.

FIG. 3 is a cross-sectional view of the adaptable collimator according to one or more embodiments in the present disclosure.

FIG. 4 is a partial top view of the deposition system according to one or more embodiments in the present disclosure.

FIG. 5 is a cross-sectional view of a cool down chamber along with the thickness measurement device that includes more than one optical measurement device according to one or more embodiments of the present disclosure.

FIG. 6 is a bottom view of a cool down chamber cover along with the thickness measurement device that includes more than one optical measurement device according to one or more embodiments of the present disclosure.

FIG. 7 is a sectional view of the target along with ultrasonic sensors in the substrate process chamber according to one or more embodiments in the present disclosure.

FIG. 8 is a sectional view of the substrate process chamber measuring an aspect ratio of gap structures on the substrate with a shutter disk according to one or more embodiments in the present disclosure.

FIG. 9 is a top view of one hollow structure in the adaptable collimator according to one or more embodiments in the present disclosure.

FIG. 10 is a side exploded view of one hollow structure in the adaptable collimator according to one or more embodiments in the present disclosure.

FIGS. 11 and 12 are side views of one hollow structure in the adaptable collimator according to one or more embodiments in the present disclosure.

FIG. 13 is a flow chart illustrating a method of increasing uniformity of a thin film deposited on subsequent substrates according to one or more embodiments in the present disclosure.

FIG. 14 is a flow chart illustrating a method of adjusting each of the hollow structures based on an aspect ratio of gap structure on the substrate according to one or more embodiments in the present disclosure.

FIG. 15 is a flow chart illustrating a method of adjusting each of the hollow structures based on target erosion profile measurement according to one or more embodiments in the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments in accordance with the subject matter described herein include a deposition system that is able to deposit a thin film (or a layer) on a substrate (e.g., contact or via structures on the wafer) with an enhanced gap-fill capability provided by an adaptable collimator. The adaptable collimator according to one or more embodiments disclosed in the present disclosure is able to adjust its dimension (e.g., length for each of hollow structures in the adaptable collimator) to deposit (or fill) target material in gaps with various aspect ratio (e.g., high aspect ratio) in patterns (such as steps and trenches) on the substrate. In addition, the adaptable collimator according to one or more embodiments disclosed in the present disclosure is able to provide uniform deposition for all areas on the substrate by adjusting its dimension (e.g., length for each of hollow structures in the adaptable collimator). In various embodiments, the adaptable collimator is able to extend the lifetime of the target by adjusting its dimension (e.g., length for each of hollow structures in the adaptable collimator). In accordance with various embodiments of the present disclosure, the adaptable collimator, having a plurality of hollow structures, is positioned between the target and the substrate.

As discussed above, during the sputtering process, the positively charged argon ions strike the target surface, and the momentum of the positively charged argon ions transfers to the target material to dislodge one or more atoms deposited on the substrate along various traveling paths.

Embodiments of such a deposition system with the adaptable collimator can deposit (or fill) the target material into gaps with a high aspect ratio on the substrate by capturing (or filtering) the target material that is likely to hinder the gap filling before arriving on the substrate based on the traveling path of the target material. For example, if the target material traveling to the gap is on a traveling path to the bottom surface of the gap (e.g., vertical direction), the gap is more likely filled with the material from the bottom surface of the gap. However, if the deposit material traveling to the gap is on a path to the side wall of the gap (e.g., inclined direction), the gap is more likely to be blocked at the top opening of the gap without having the target material filled all the way to the bottom of the gap. It is helpful to reduce the target material that is likely to block the gap, especially for the gap with a high aspect ratio, by having a plurality of long narrow passages (e.g., hollow structures) between the target and the substrate. In some embodiments, each of the hollow structures in the adaptable collimator are configured to extend individually or collectively to capture the target material that is likely to deposit on the side wall of the gap based on the aspect ratio of the gap (e.g., length for the hollow structures increases as the aspect ratio of the gap increases) to improve the gap-fill capability of the deposit system.

In some embodiments of the present disclosure, by adjusting a respective length for each of the hollow structures individually or collectively, the deposit system is able to fill the gap with the high aspect ratio. In some embodiments of the present disclosure, by adjusting the respective length for each of the hollow structures in the adaptable collimator individually or collectively, the deposit system is able to deposit a uniform layer on the substrate. In some embodiments, by adjusting the respective length for each of the hollow structures in the adaptable collimator individually or collectively, the deposition system is able to stabilize a deposition rate for a longer time — extending the target lifetime.

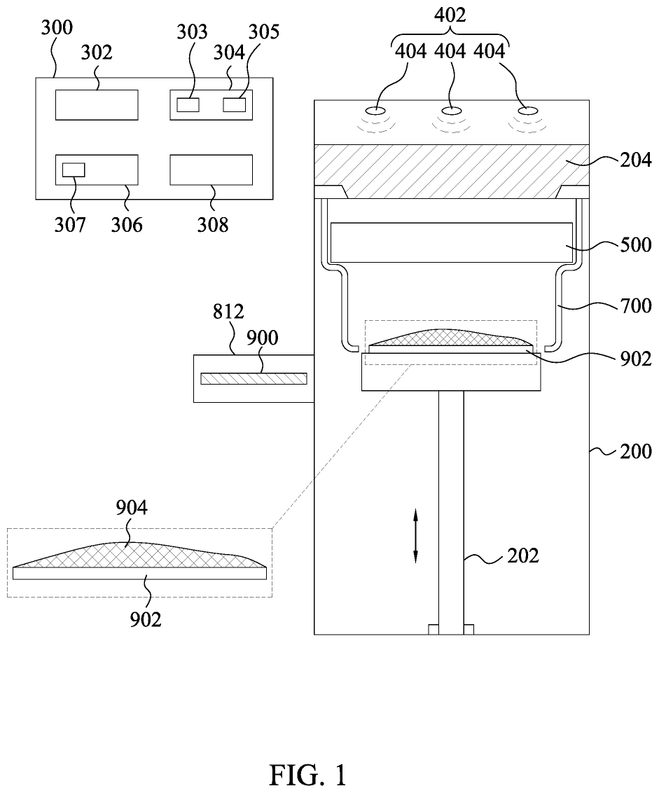

FIG. 1 is a sectional view of a substrate process chamber 200 in the deposition system 100 according to one or more embodiments in the present disclosure.

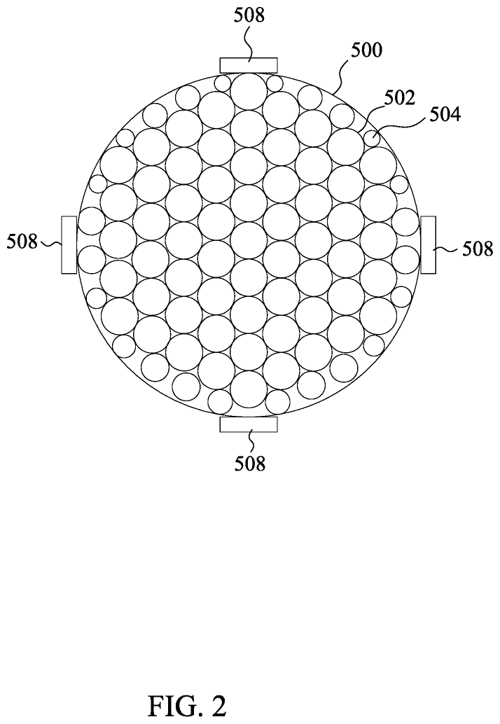

FIG. 2 is a top view of the adaptable collimator 500 according to one or more embodiments in the present disclosure.

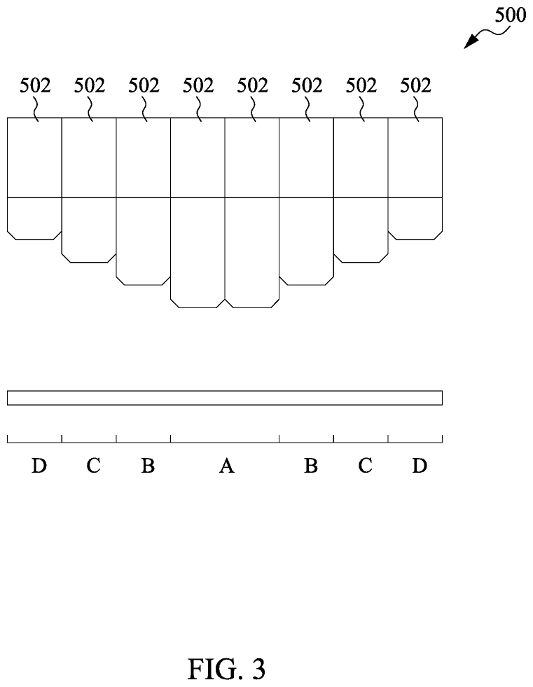

FIG. 3 is a cross-sectional view of the adaptable collimator 500 according to one or more embodiments in the present disclosure.

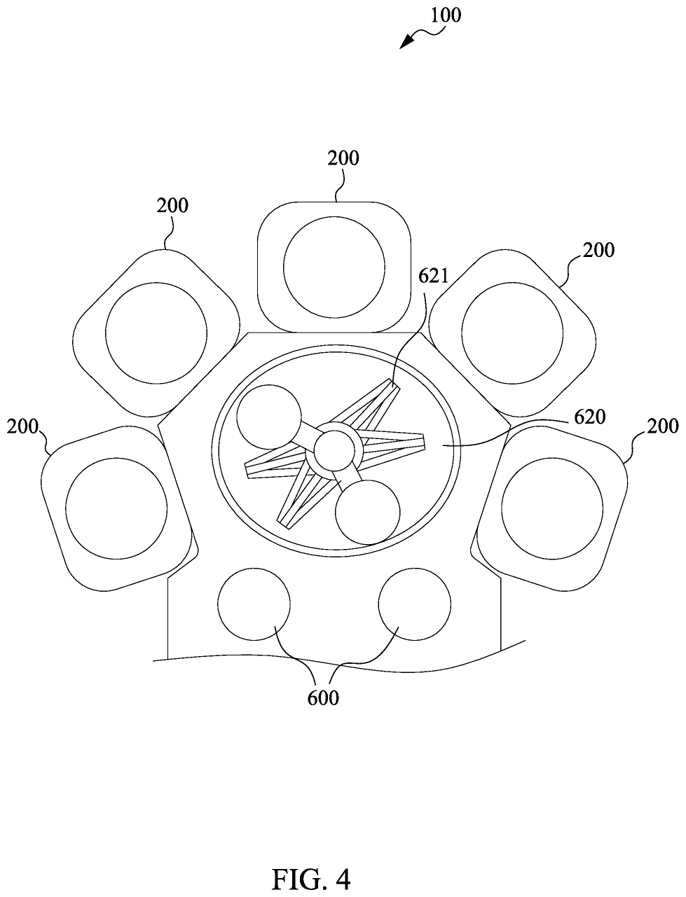

FIG. 4 is a partial top view of the deposition system 100 according to one or more embodiments in the present disclosure.

Referring to FIG. 1, the substrate process chamber 200 includes a substrate pedestal 202 that supports a substrate 902 (e.g., wafer) in the substrate process chamber 200, a target 204 enclosing the substrate process chamber 200, a process shield 700 between the target 204 and substrate pedestal 202, and an adaptable collimator 500 disposed in or near an inner side of the process shield 700 between the target 204 and the substrate pedestal 202.

Referring to FIG. 2, the adaptable collimator 500 includes a plurality of hollow structures 502 configured to adjust a respective length for each of the hollow structures 502 based on a configuration control signal from a controller 300 (e.g., extend or retract to a determined length). In various embodiments of the present disclosure, the plurality of hollow structures 502 is clustered to provide a plurality of openings 504 where the material from the target 204 passes through. In other words, the hollow structures 502 provide narrow passages between the target 204 and the substrate 902. In some embodiments, each hollow structure overlaps a portion of the underlying substrate 902. A length for each of the narrow passages (hollow structure 502) effect a corresponding area on the substrate 902. For example, by extending one of the hollow structures 502, a gap with a high aspect ratio on the corresponding area on the substrate 902 is likely to fill without having void or overhang issues. In addition, by retracting one of the hollow structures 502, more target material is deposited on the corresponding area on the substrate 902. In various embodiments, to increase or to adjust the amount of the material from the target 204 that passes through the openings 504, the plurality of openings 504 includes the openings 504 in various sizes and shapes (e.g., circular shape, triangular shape, quadrilateral shape, pentagonal shape, hexagonal shape, heptagonal shape, and octagonal shape). In some embodiments of the present disclosure, the adaptable collimator 500 includes a coupling mechanism 506 that is used to attach the adaptable collimator 500 to the inner side of the process shield 700. In the illustrated embodiment shown in FIG. 2, the adaptable collimator 500 is coupled to the process shield 700 using four screw coupling locations 508.

Referring to FIG. 3, each of the hollow structures 502 in the adaptable collimator 500 is adjusted based on the configuration control signal from the controller 300. Based on the configuration control signal from the controller 300, the respective length for each of the hollow structures 502 can be adjusted.

In the illustrated embodiment shown in FIG. 3, the respective length for each of the hollow structures 502 is adjusted such that the hollow structures 502 at location A are longer than the hollow structures 502 at locations B, C, and D. In the illustrated embodiment, the hollow structures 502 at location B are longer than the hollow structures 502 at locations C and D. The hollow structures 502 at location C are longer than the hollow structures 502 at location D in the illustrated embodiment.

In the illustrated embodiment, the length for each of the hollow structures 502 is incrementally changed based on the configuration control signal from the controller 300. However, the present disclosure does not limit that the length of the hollow structures 502 changes incrementally. In various embodiments, each of the hollow structures 502 is retracted or extended to a determined length.

Adaptable collimator 500 configured as illustrated in FIG. 3 provides a greater coverage for a high aspect ratio gap at the center of the substrate 902 (corresponding to location A) than a coverage for a high aspect ratio gap at the periphery area of the substrate 902 (corresponding to locations B, C, and D) since the hollow structures 502 at the location A of the adaptable collimator 500 capture or block more target material that is likely to deposit on the side wall of the gap. However, the adaptable collimator 500 configured as illustrated in FIG. 3 provides a higher deposition rate at the periphery area of the substrate 902 (corresponding to locations B, C, and D) than the center area of the substrate 902 (corresponding to location A) since less material is blocked or captured at locations B, C, and D of the adaptable collimator 500 (e.g., periphery area of the adaptable collimator 500). In other words, the respective length for each of the hollow structures 502 in the adaptable collimator 500 can be adjusted based on a size of the gap aspect ratio, a target uniformity of the thin film 904 on the substrate 902, and/or an amount of target material on each of the corresponding areas on the substrate 902.

Referring to FIG. 4, the deposition system 100 includes one or more substrate process chambers 200, one or more cool down chambers 600, a transfer chamber 620, a transfer robot arm 621 in the transfer chamber 620 configured to move the substrate 902 from one of the chambers surrounding the transfer chamber 620 to another chamber surrounding the transfer chamber 620.

Cool down chamber 600 is used to temporarily hold the substrate 902 before the substrate 902 is transferred to one of the substrate process chambers 200 for the deposition process or temporarily hold the substrate 902 after the deposition process is done at one of the substrate process chambers 200. In various embodiments of the present disclosure, the cool down chamber 600 includes a thickness measurement device 602 that is able to measure thickness from a thin film 904 deposited on the substrate 902.

The embodiment illustrated in FIG. 1 illustrates that the substrate pedestal 202 is in a process position (e.g., upper position) supporting the substrate 902 during a sputtering process. At this time, the thin film 904 is formed with the target material from the target 204 (and reactive gas supplied to the substrate process chamber 200) on the substrate 902. In various embodiments, the adaptable collimator 500 is capable of adjusting the respective length for each of the hollow structures 502 (e.g., extend or retract to a determined length) based on the thickness measurements collected at the cool down chamber 600 (in FIGS. 4-6) from the substrate 902 at a plurality of locations after the deposition at the substrate process chamber 200 is completed.

As discussed above, in various embodiments of the present disclosure, the adaptable collimator 500 is capable of adjusting the respective length for each of the hollow structures 502 to provide the uniform deposition rate at all locations on subsequent substrates. For example, at least one of the hollow structures 502 can be extended to reduce the deposition rate (e.g., amount of the target material) at a corresponding location (e.g., where the substrate process chamber 200 deposited excessive amount of material on the substrate 902) on the subsequence substrates. In addition, at least one of the hollow structures 502 can be retracted to increase the deposition rate (amount of the deposited material) at a corresponding location (e.g., where the substrate process chamber 200 previously deposited less amount of material on the substrate 902) on the subsequent substrates. By increasing and/or decreasing the deposition rates at different corresponding locations on the subsequent substrates, the substrate process chamber 200 can provide uniform deposition on the subsequent substrates.

Referring to FIGS. 1 and 3, FIG. 3 illustrates the adaptable collimator 500 configured for the subsequent substrates for uniform deposition after thickness measurement is completed on the thin film 904 illustrated in FIG. 1. Based on the thickness measurement, a respective length for each of the hollow structure 502 is determined. In some embodiments, by comparing a predetermined thickness of the thin film 904 with the measured thickness of the thin film 904 at each of the locations, the respective length for each of a plurality of hollow structures 502 in a collimator 500 is determined. At as a result, when the thickness of the film 904 at one location (one or more locations) is greater than the predetermined thickness, the hollow structures 502 corresponding to the location is increased (e.g., extended to the determined length). Also, when the thickness of the film 904 at one (one or more locations) is less than the predetermined thickness, the hollow structures 502 corresponding to the location is decreased (e.g., retracted to the determined length). The amount of retraction or extension is proportion to the difference between the predetermined thickness of the film 904 and the measured thickness of the film 904 at the locations on the substrate 902. In some embodiments, by comparing an average thickness of the thin film 904 (based on the measured thickness of the thin film 904) with the measured thickness of the thin film 904 at each of the locations, the respective length for each of a plurality of hollow structures 502 in a collimator 500 is determined. At as a result, when the thickness of the film 904 at one location (one or more locations) is greater than the average thickness, the hollow structures 502 corresponding to the locations is increased (e.g., extended to the determined length). Also, when the thickness of the film 904 at one (one or more locations) is less than the average thickness, the hollow structures 502 corresponding to the location is decreased (e.g., retracted to the determined length). The amount of retraction or extension is proportion to the difference between the average thickness of the film 904 and the measured thickness of the film 904 at the locations on the substrate 902.

As discussed above, the hollow structures 502 can be extended to reduce the deposition rate (e.g., amount of the target material) at a corresponding location (center area for this case), and the hollow structures 502 can be retracted to increase the deposition rate (amount of the deposited material) at a corresponding location (wafer edge area for this case).

By optimizing the respective length for each of the hollow structures 502 in the adaptable collimator 500, less target material is likely to deposit on the adaptable collimator 500 that can reduce the production yield (e.g., chamber particle issue due to particles peeled from a collimator). In addition, by optimizing the respective length for each of the hollow structures 502 in the adaptable collimator 500, more target material is actually utilized for deposition.

As discussed above, in some embodiments, uniformity (or thickness) of the deposited layer (thin film 904) is measured with the thickness measurement device 602 located in the cool down chamber 600. However, the present disclosure does not limit the location of the measurement. In some embodiments, the measurement can be done in other locations in the deposition system 100 (e.g., substrate process chamber 200). In some embodiments, the measurements can be done by a metrology tool.

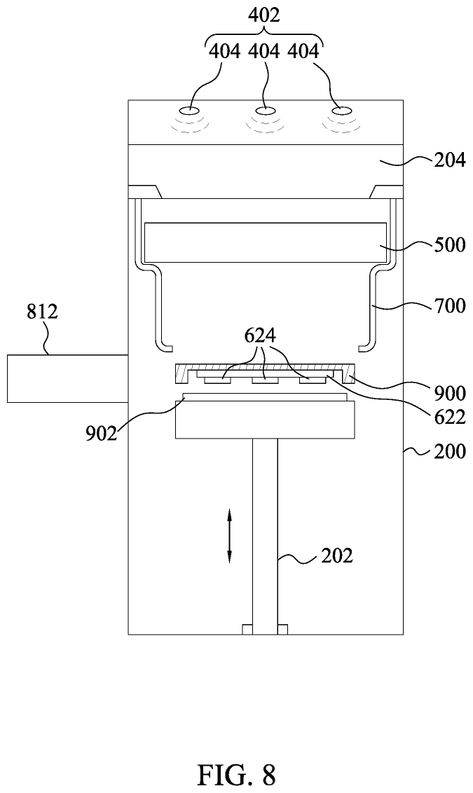

In accordance with various embodiments, the substrate process chamber 200 includes an aspect ratio measurement device 622 (in FIG. 8) that is able to measure the aspect ratio of the gap in the patterns on the substrate 902. In the illustrated embodiment in FIG. 1, a shutter disk 900 includes the aspect ratio measurement device 622 having one or more image analysis devices 624 (in FIG. 8) (e.g., image sensors) that can measure the aspect ratio of the gap in the patterns on the substrate 902. Details of the aspect ratio measurement device 622 will be provided later in the present disclosure.

As discussed above, in various embodiments, the adaptable collimator 500 is capable of adjusting the respective length for each of the hollow structures 502 to improve step coverage for filling the high aspect ratio gap in the patterns on the substrate 902. For example, the hollow structures 502 in the adaptable collimator 500 can be extended collectively to improve the step coverage for the high aspect ratio gap in the patterns on the substrate 902. As indicated above, by extending the hollow structures 502, the deposition rate of the substrate process chamber 200 is reduced. So, the hollow structures 502 in the adaptable collimator 500 can be retracted collectively to a certain length for filling low aspect ratio gap in the patterns on the substrate 902 to maintain a certain deposition rate for production throughput.

As discussed above, by optimizing the respective length for each of the hollow structures 502 in the adaptable collimator 500, less target material is likely to deposit on the adaptable collimator 500 that can reduce the production yield (e.g., chamber particle issue due to particles peeled from a collimator). In addition, by optimizing the respective length for each of the hollow structures 502 in the adaptable collimator 500, more target material is actually utilized for deposition.

As discussed above, in some embodiments, the aspect ratio of the gap in the patterns on the substrate 902 is measured with the aspect ratio measurement device 622 located in the substrate process chamber 200. However, the present disclosure does not limit the location of the measurement. In some embodiments, the measurement can be done in other locations in the deposition system 100 (e.g., cool down chamber 600). In some embodiments, the measurements can be done by a metrology tool. In some embodiments, the aspect ratio is predetermined or included in the deposition process recipe.

In accordance with various embodiments, the substrate process chamber 200 includes a target thickness measurement device 402 capable of measuring a thickness of the target 204 at a plurality of locations (e.g., target erosion profile measurement). A sensor used by the target thickness measurement device 402 can be any type of sensor that is suitable to perform a non-destructive inspection. In the embodiment illustrated in FIG. 1, the ultrasonic sensors are positioned above the target 204. Ultrasonic sensor 404 is used to measure the thickness of the target 204 at a plurality of locations in a non-destructive manner. The embodiment illustrated in FIG. 1 shows that three ultrasonic sensors 404 are located above the target 204. However, the present disclosure does not limit the location of the ultrasonic sensor 404 and/or number of the ultrasonic sensor 404. In addition, the ultrasonic sensor 404 can be placed in any suitable locations for monitoring the thickness of the target 204 (e.g., target erosion profile). Details of the ultrasonic sensor 402 will be provided later in the present disclosure.

As discussed above, in various embodiments, the adaptable collimator 500 is capable of adjusting the respective length for each of the hollow structures 502 to stabilize the deposit rate to maintain uniform deposition for all areas on the substrate 902. For example, the hollow structures 502 can be extended or retracted to stabilize the deposition rate based on the target erosion profile. By retracting (or maintaining) the length of the hollow structures 502 corresponding to locations where less target material remained on the target 204 (which leads to less materials exiting from the target surface), and by extending the length of the hollow structures 502 corresponding to locations where more target material remains on the target 204 (which leads more material exiting the target surface), the substrate process chamber 200 can maintain the deposition rate while maintaining the uniformity of the layer deposited in the substrate process chamber 200.

As discussed above, by optimizing the respective length for each of the hollow structures 502 in the adaptable collimator 500, less target material is likely to deposit on the adaptable collimator 500 that can reduce the production yield (e.g., chamber particle issue due to particles peeled from a collimator). In addition, by optimizing the respective length for each of the hollow structures 502 in the adaptable collimator 500, more target material is actually utilized for deposition.

Controller 300 controls the respective length for each of the hollow structures 502 in the adaptable collimator 500 (e.g., extend and retract). In accordance with one or more embodiments of the present disclosure, the controller 300 includes an input circuitry 302, a memory 304, a processor 306, and an output circuitry 308. Controller 300 includes the (computer) processor 306 configured to perform the various functions and operations described herein including receiving input data from various data sources (e.g., measurement data from thickness measurement device 602, aspect ratio measurement device 622, and/or target thickness measurement device 402) via the input circuity 302 and transmitting output data (e.g., configuration control signal) to the adaptable collimator 500 via the output circuitry 308. Input circuitry 302 receives the thickness measurement, aspect ratio measurement, and/or target erosion profile measurement measured by respective measurement devices (e.g., thickness measurement device 602, aspect ratio measurement device 622, and/or target thickness measurement device 402).

In some embodiments of the present disclosure, the thin film thickness measurement is taken at one location or a plurality of (predetermined or random) locations on the substrate 902. In some embodiments, the input circuitry 302 also receives process specification information such as a target thin film thickness. Details of the input circuitry 302, memory 304, and output circuitry 308 will be provided later in the present disclosure.

In some embodiments, the processor 306 determines at least one area or location (e.g., center area, wafer edge area, and area between the center area and the wafer edge area) where the thickness of the thin film 904 is out of or within the process specification. Based on the determination, the processor 306 determines a precise length for each of the hollow structures 502 (or relevant hollow structures 502) in the adaptable collimator 500. In some embodiments, the processor 306 determines a precise length for each of the hollow structures 502 (or relevant hollow structures 502) in the adaptable collimator 500 based on the aspect ratio measurement. In some embodiments, the processor 306 determines a precise length for each of the hollow structures 502 (or relevant hollow structures 502) in the adaptable collimator 500 based on the target erosion profile measurement.

Memory 304 stores information received via the input circuitry 302 and the processed data such as the determined location (area) information from the processor 306. Memory 304 may be or include any computer-readable storage medium, including, for example, read-only memory (ROM), random access memory (RAM), flash memory, hard disk drive, optical storage device, magnetic storage device, electrically erasable programmable read-only memory (EEPROM), organic storage media, or the like. Output circuitry 308 transmits the configuration control signal (e.g., extend or retract) for the adaptable collimator 500 based on the measurement data.

In accordance of one or more embodiments of the present disclosure, the processor 306 transmits the configuration control signal to the adaptable collimator 500 based on the measurement data from the respective measurement devices (thickness measurement device 602, aspect ratio measurement device 622, and/or target thickness measurement device 402).

In a non-limiting example, based on the measurement data from the thickness measurement device 602, the processor 306 determines at least one location on the substrate 902 (e.g., center area, edge area, and area between the center and the edge areas) where less target material is deposited than intended based on the process specification. Processor 306 transmits the configuration control signal to the adaptable collimator 500 and based on the configuration control signal, the adaptable collimator 500 adjusts the length for each of the hollow structures 502 (or relevant hollow structures 502) for the subsequent substrates. For instance, if the processor 306 determines that there is less target material deposited on the edge of the substrate 902 than intended by the process recipe, the processor 306 transmits the configuration control signal to retract the hollow structures 502 (e.g., shorter length for the hollow structures 502) at corresponding locations for subsequent substrates. As a result, a desired amount of target material is deposited on the edge of the subsequent substrates accordingly.

In a non-limiting example, based on the measurement data from the target thickness measurement device 402 that measures the target erosion profile from the target 204, the processor 306 determines at least one location on the target 204 (e.g., center area, edge area, and area between the center and the edge areas) where less target material remains compared to other locations on the target 204. Processor 306 transmits the configuration control signal to the adaptable collimator 500 and based on the configuration control signal, the adaptable collimator 500 adjusts the length for each of the hollow structures 502 (or relevant hollow structures 502). For instance, if the processor 306 determines that there is less target material remaining on the edge of the target 204 than other locations on the target 204, the processor 306 transmits the configuration control signal to the adaptable collimator 500 to retract the hollow structures 502 (e.g., shorter length for the hollow structures) in the periphery area. As a result, the deposition rate for an area on the substrate 902 corresponding to the edge of the target 204 and the deposition rate for other areas on the substrate 902 are the same or in other embodiments could be greater for a period of time. Accordingly, the substrate process chamber 200 can deposit a uniform thin film layer while maintaining the stable deposition rate or a deposition rate that is different than the deposition rate onto other areas of the substrate.

In a non-limiting example, based on the measurement data from the aspect ratio measurement device 622, the processor 306 determines the aspect ratio of gap in the patterns on the substrate 902. Processor 306 transmits the configuration control signal to the adaptable collimator 500 and based on the configuration control signal, the adaptable collimator 500 adjusts the length for each of the hollow structures 502 (or relevant hollow structures 502). For instance, if the processor 306 determines that substrate 902 includes the high aspect ratio gap in the patterns on the substrate 902, the processor 306 transmits the configuration control signal to extend the hollow structures 502 to fill the gap with the high aspect ratio.

Output circuitry 308 may be or include one or more output terminals that are communicatively coupled to any desired number of components of the deposition system 100 such as the adaptable collimator 500. Details of the measurement device 602, aspect ratio measurement device 622, and target thickness measurement device 402 will be provided later in the present disclosure.

In some embodiments, the processor 306 includes a collimator configuration generator (artificial intelligence controller) 307 that is used to determine the respective length for each of the hollow structures 502 by employing one or more artificial intelligence techniques.

“Artificial intelligence” is used herein to broadly describe any computationally intelligent systems and methods that can learn knowledge (e.g., based on training data), and use such learned knowledge to adapt their approaches for solving one or more problems, for example, by making inferences based on a received input such as measurements (measurement data) received via the input circuitry 302. Artificially intelligent machines may employ, for example, neural network, deep learning, convolutional neural network, Bayesian program learning, and pattern recognition techniques to solve problems such as determining the respective length for each of the hollow structures 502. Further, artificial intelligence may include any one or combination of the following computational techniques: constraint program, fuzzy logic, classification, conventional artificial intelligence, symbolic manipulation, fuzzy set theory, evolutionary computation, cybernetics, data mining, approximate reasoning, derivative-free optimization, decision trees, and/or soft computing. Employing one or more computationally intelligent techniques, the collimator configuration generator 307 may learn to determine the respective length for each of the hollow structures 502 (or relevant hollow structures 502) in the adaptable collimator 500.

In some embodiments, the collimator configuration generator 307 is trained based on training data 303 stored in the memory 304. In some embodiments, the training data 303 includes predetermined lengths for the hollow structure 502 for various conditions. For a non-limiting example, the training data 303 includes the predetermined length for the hollow structure 502 corresponding to different target 204 thickness (target erosion profile), different aspect ratios of gap patterns, different thin film 904 thickness (including measurement taken before deposition for pre-layers previously deposited on the substrate 902), circuit design minimum space information (e.g., gap-fill information), and any combinations therefore.

In some embodiments, based on the training data 303, the collimator configuration generator 307 controls and/or adjusts the respective length for each of the hollow structures 502 (or relevant hollow structures 502).

In some embodiments, the collimator configuration generator 307 learns to modify its behavior in response to the training data 303 and obtain or generate collimator configuration knowledge which is stored in a collimator configuration database 305. The configuration knowledge includes result of operating the deposition system 100 (e.g., deposition) using the training data 303 such as thin film (904) uniformity and corresponding training data 303 used, fabrication yield for gap fill process and corresponding training data 303 used, and target (204) life-time and corresponding training data 303 used. These results from the deposition based on the training data 303 (e.g., uniformity of the thin film (904), life-time of the target (204), erosion profile of the target (204), and/or fabrication yield related to gap fill result) can be obtained using one or more sensors (e.g., ultrasonic sensor, infrared sensor, laser sensor, light detection and ranging sensor, sound navigation ranging sensor, and/or image sensor) located within the deposition system 100.

In some embodiments, based on the collimator configuration knowledge (including the results from the deposition), the collimator configuration generator 307 makes corrections to the training data 303 to optimize or improve the training data 303 to a particular substrate process chamber 200. In other words, the collimator configuration generator 307 continuously modifies its behavior in response to the training data 303 and the collimator configuration database 305 and updates the collimator configuration knowledge in the collimator configuration database 305.

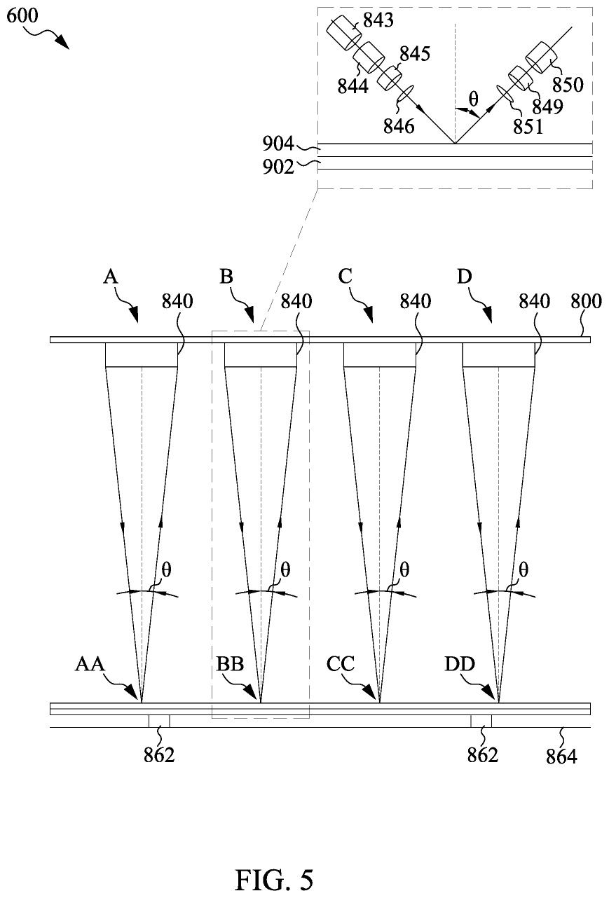

FIG. 5 is a cross-sectional view of the cool down chamber 600 along with the thickness measurement device 602 that includes more than one optical measurement device 840 according to one or more embodiments of the present disclosure.

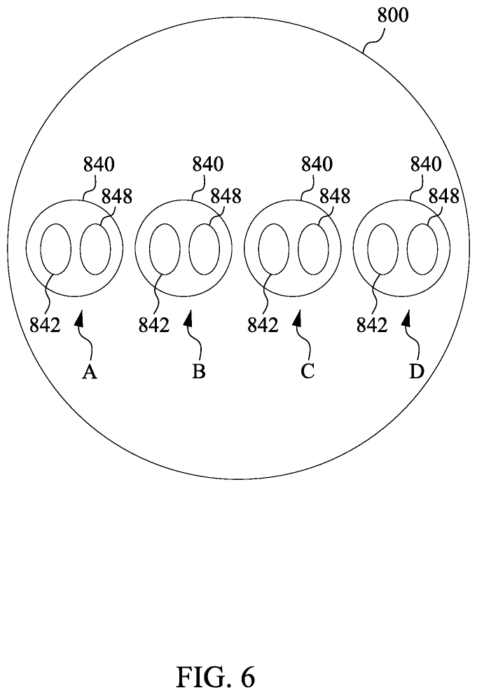

FIG. 6 is a bottom view of a cool down chamber cover 800 along with the thickness measurement device 602 that includes more than one optical measurement device 840 according to one or more embodiments of the present disclosure.

Referring to FIGS. 5 and 6, each of the optical measurement devices 840 includes a light source 842 that is configured to emit a linearly polarized light (e.g., linearly polarized laser) to the thin film 904 on the substrate 902 and a light detector 848 that is configured to detect the light reflected from the thin film 904 (e.g., reflected ellipse) in accordance with one or more embodiments of the present disclosure. Based on the shape of the reflected ellipse and an angle of the reflection 0, the thickness of the thin film 904 on the substrate 902 can be determined. Substrate 902 is placed on a plurality of fins 862 on a bottom of the chamber 864 while the substrate 902 is in the cool down chamber 600.

In the illustrated embodiment in FIGS. 5 and 6, the optical measurement devices 840 are placed above the substrate 902 at a certain distance to measure the thickness of the thin film 904 on the substrate 902. Each of the optical measurement devices 840 includes the light source 842 that is configured to emit the linearly polarized light (e.g., linearly polarized laser) to the thin film 904 on the substrate 902 and a light detector 848 that is configured to detect the light reflected (e.g., reflected ellipse) from the thin film 904. Based on the shape of the reflected ellipse and the angle of the reflection 0, the thickness of the thin film 904 on the substrate 902 is determined. To produce the light that is polarized linearly, the light source 842 includes a laser 843 and a polarizer 845 in accordance with one or more embodiments of the present disclosure. In addition to the laser 843 and the polarizer 845, the light source 842 includes a filter 844 and a quarter wave plate 846 to generate the linearly polarized light from the laser 843 as shown in the illustrated embodiment in FIG. 5. In some embodiments of the present disclosure, the light detector 848, including an analyzer 849 and a detector 850, receives and detects the shape of the reflected ellipse. As discussed above, based on the shape of the reflected ellipse and an angle of the reflection 0, the thickness of the thin film 904 on the substrate 902 is determined.

Referring to FIGS. 5 and 6, the thickness measurement device 602 includes more than one optical measurement device 840 to measure the thickness of the thin film 904 at the plurality of locations on the substrate 902. In the illustrated embodiment in FIGS. 5 and 6, four optical measurement devices 840 are located on the bottom of the cover 800 to measure the thickness of corresponding locations on the thin film 904. For a non-limiting example, the optical measurement device 840 located at location A on the cool down chamber cover 800 is configured to measure the thickness of the thin film 904 at location AA, an optical measurement device 840 located at location B on the cool down chamber cover 800 is configured to measure the thickness of the thin film 904 at location BB, the optical measurement device 840 located at C on the cool down chamber cover 800 is configured to measure the thickness of the thin film 904 at location CC, and the optical measurement device 840 located at location D on the cool down chamber cover is configured to measure the thickness of the thin film 904 at location DD.

In some embodiments, the thickness of the thin film 904 at the locations AA, BB, CC, and DD are taken sequentially in a predetermined order with the corresponding optical measurement devices 840 at respective locations A, B, C, and D.

In some embodiments, to increase the production throughput (e.g., reducing time for the measurement), the thickness of the thin film 904 at AA, BB, CC, and DD are taken simultaneously by the corresponding optical measurement devices 840 at locations A, B, C, and D. To increase accuracy of the thickness measurement by reducing interference due to the simultaneous measurement, each of the corresponding optical measurement devices 840 has the light source 842 that generates the light (e.g., laser beam) with a distinctive wavelength that is different from the others. In a non-limiting example, the light source 842 of the optical measurement device 840 at the location A emits the light with a first wavelength to the location AA on the substrate 902, and the light detector 848 of the optical measurement device 840 at the location A, which is configured to detect the light in the first wavelength, detects the reflected ellipse in the first wavelength from the location AA. In some embodiments of the present disclosure, the light detector 848 of the optical measurement device 840 at the location A includes a light filter 851 to block other light in different wavelengths so only the reflected ellipse in the first wavelength is detected by the light detector 848.

Similar to the light source 842 of the optical measurement device 840 at the location A, the light source 842 of the optical measurement device 840 at the location B emits the light with a second wavelength to the location BB on the substrate 902, and the light detector 848 of the optical measurement device 840 at the location B, which is configured to detect the light in the second wavelength, detects the reflected ellipse in the second wavelength from the location BB. In some embodiments of the present disclosure, the light detector 848 of the optical measurement device 840 at the location B includes a light filter 851 to block other light in different wavelengths so only the reflected ellipse in the second wavelength is detected by the light detector 848.

Similar to the light source 842 of the optical measurement device 840 at the location A, the light source 842 of the optical measurement device 840 at the location C emits the light with a third wavelength to the location CC on the substrate 902, and the light detector 848 of the optical measurement device 840 at the location C, which is configured to detect the light in the third wavelength, detects the reflected ellipse in the third wavelength from the location CC. In some embodiments of the present disclosure, the light detector 848 of the optical measurement device 840 at the location C includes a light filter 851 to block other light in different wavelengths so only the reflected ellipse in the third wavelength is detected by the light detector 848.

Similar to the light source 842 of the optical measurement device 840 at the location A, the light source 842 of the optical measurement device 840 at the location D emits the light with a fourth wavelength to the location DD on the substrate 902, and the light detector 848 of the optical measurement device 840 at the location D, which is configured to detect the light in the fourth wavelength, detects the reflected ellipse in the fourth wavelength from the location DD. In some embodiments of the present disclosure, the light detector 848 of the optical measurement device 840 at the location D includes a light filter 851 to block other light in different wavelengths so only the reflected ellipse in the fourth wavelength is detected by the light detector 848.

In some embodiments of the present disclosure, some of the light generated from the light sources 842 is in the same wavelength if the light sources 842 are spaced apart by a predetermined distance or by a predetermined number of light sources 842. In a non-limiting example, each of the light sources 842 at the locations A and C emits the light in the same wavelength. Similarly, each of the light sources 842 at the locations B and D emits the light in the same wavelength.

In FIGS. 5 and 6, the thickness measurement device 602 includes optical measurement device 840 that is located in the cool down chamber 600 to measure the thin film 904 on the substrate 602. However, the present disclosure does not limit the location of the thickness measurement device 602. Also the present disclosure does not limit sensing method for the measurement. For non-limiting example, in some embodiments, the thickness measurement device 602 includes at least one of ultrasonic sensor, infrared sensor, laser sensor, light detection and ranging sensor, sound navigation ranging sensor, or image sensor.

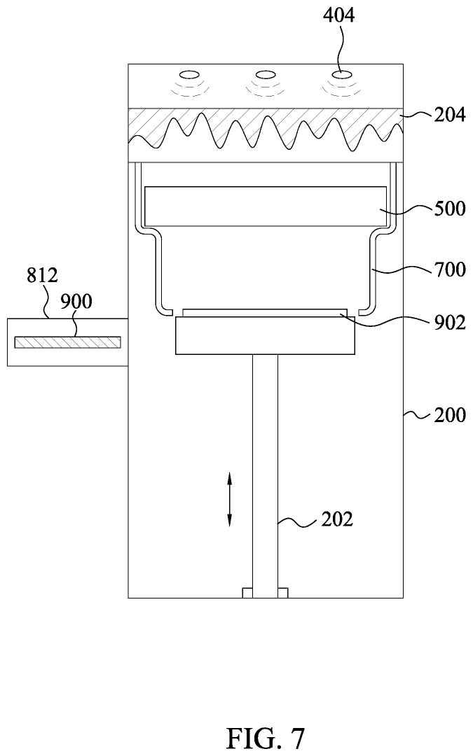

FIG. 7 is a sectional view of the target 204 along with the ultrasonic sensors 404 in the substrate process chamber 200 according to one or more embodiments in the present disclosure.

Referring to FIG. 7, the substrate process chamber 200 according to one or more embodiments of the present disclosure includes three ultrasonic sensors 404.

In the illustrated embodiment, three ultrasonic sensors 404 are located above the target 204. Each of the ultrasonic sensors 404 measures the thickness of the target 204 in a respective target area using at least one non-destructive testing technique based on the propagation of ultrasonic waves. For instance, in accordance with embodiments illustrated in FIG. 2, each of the ultrasonic sensors 404 generates a short ultrasonic pulse wave with center frequencies between 0.1 MHz and 50 MHz and propagates the ultrasonic pulse waves into the target 204. Ultrasonic sensors 404 measure the thickness of the target 204 in the respective area by comparing the initial ultrasonic pulse waves generated by the ultrasonic sensors 402 and the ultrasonic pulse waves reflected from the target 204.

Embodiments in accordance with the present disclosure are not limited to using the short ultrasonic pulse-wave with center frequencies between 0.1 MHz and 50 MHz. For non-limiting example, in other embodiments in accordance with the present disclosure, the center frequency is below 0.1 MHz or above 50 MHZ. In accordance with embodiments of the present disclosure, a waveform generated by the ultrasonic sensor 402 is not limited to the pulse wave. For a non-limiting example, in other embodiments in accordance with the present disclosure, the waveform can be in any suitable waveform capable of measuring a thickness of the target 204 such as a sine waveform, triangle waveform, and sawtooth waveform.

Embodiments in accordance with the present disclosure are not limited to using three ultrasonic sensors 404. For instance, in other embodiments in accordance with the present disclosure, two or more ultrasonic sensors 404 are (evenly or unevenly) positioned above the target 204 based on the size of the target 204. However, only one ultrasonic sensor 404 may be positioned on the target 204 if having one ultrasonic sensor 404 is sufficient to measure the thickness of the target 204 at the plurality of locations. Alternatively, one or more moveable ultrasonic sensor 404 may be used to measure the thickness of the target at the plurality of locations.

As discussed above, in various embodiments, the adaptable collimator 500 is capable of adjusting the respective length for each of the hollow structures 502 to stabilize the deposit rate to maintain uniform deposition for all areas on the substrate 902. For example, the hollow structures 502 can be extended or retracted to stabilize the deposition rate based on the target erosion profile. By retracting (or maintaining) the length of the hollow structures 502 corresponding to locations where less target material remained on the target 204 (which leads to less materials exiting from the target surface), and by extending the length of the hollow structures 502 corresponding to locations where more target material remains on the target 204 (which leads more material exiting the target surface), the substrate process chamber 200 can maintain the deposition rate while maintaining the uniformity of the layer deposited in the substrate process chamber 200. In some embodiments, the target erosion profile (e.g., target thickness at the plurality of locations) is measured using a wafer swap interval setting in the process recipe.

In FIG. 7, the target thickness measurement device 402 includes ultrasonic sensors 404 that are located in substrate process chamber 200 to measure the target 204. However, the present disclosure does not limit the location of the target thickness measurement device 402. Also the present disclosure does not limit sensing method for the measurement. For non-limiting example, in some embodiments, the target thickness measurement device 202 includes at least one of ultrasonic sensor, infrared sensor, laser sensor, light detection and ranging sensor, sound navigation ranging sensor, or image sensor.

FIG. 8 is a sectional view of the substrate process chamber 200 measuring the aspect ratio of the gap in the patterns on the substrate 902 with a shutter disk 900 according to one or more embodiments in the present disclosure.

Referring to FIG. 8, before the deposition process shown in FIG. 1, the substrate pedestal 202 that supports the substrate 902 is at a measurement position (e.g., lower position) with the substrate 902 so the substrate 902 is positioned closer to the bottom inner surface of the substrate process chamber 200. While the substrate pedestal 202 is in the measurement position, the shutter disk 900, which is generally stored in the shutter disk storage 812 when it is not in use, is placed above the substrate 902 at a certain distance from the substrate 902 in order to measure the aspect ratio of the gap structures on the substrate 902.

In the illustrated embodiment in FIG. 8, the shutter disk 900 with the aspect ratio measurement device 622 is positioned above the substrate 902 for the aspect ratio measurement.

In the illustrated embodiment in FIG. 8, the aspect ratio measurement device 622 on the shutter disk 900 includes the plurality of image analysis devices 624 that can capture and analysis the patterns on the substrate 902 as illustrated in FIG. 8. As discussed above, the aspect ratio of the gap in the patterns on the substrate 902 is measured using the image analysis devices 624. In some embodiments, the aspect ratio of the gap in the patterns is measured using a wafer swap interval setting in the process recipe.

The present disclosure does not limit the number of the image analysis devices 624 in the aspect ratio measurement device 622. Accordingly, in some embodiments of the present disclose, the aspect ratio measurement device 622 includes less than two image analysis devices 624 or more than two image analysis devices 624.

In FIG. 8, the aspect ratio measurement device 622 includes image analysis device 604 that are located on the shutter disk 900 to measure the aspect ratio of gap. However, the present disclosure does not limit the location of the aspect ratio measurement device 622. Also the present disclosure does not limit sensing method for the measurement. For non-limiting example, in some embodiments, the aspect ratio measurement device 622 includes at least one of ultrasonic sensor, infrared sensor, laser sensor, light detection and ranging sensor, sound navigation ranging sensor, or image sensor.

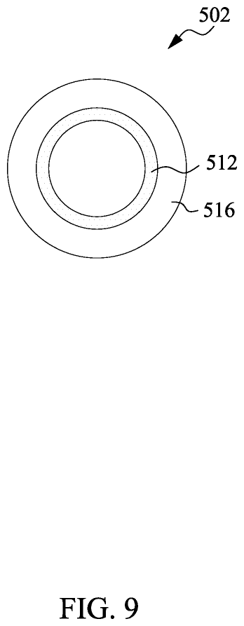

FIG. 9 is a top view of one hollow structure 502 in the adaptable collimator 500 according to one or more embodiments in the present disclosure.

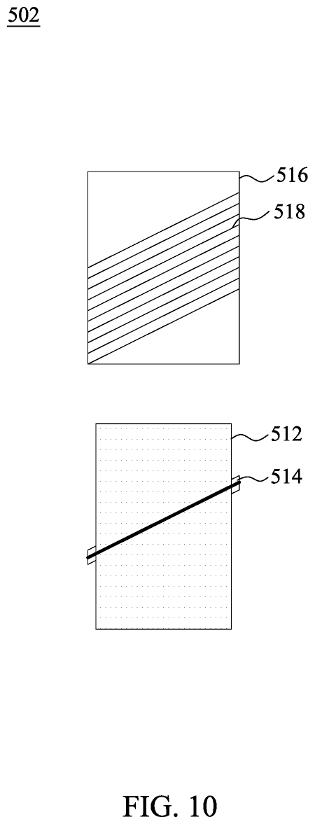

FIG. 10 is a side exploded view of one hollow structure 502 in the adaptable collimator 500 according to one or more embodiments in the present disclosure.

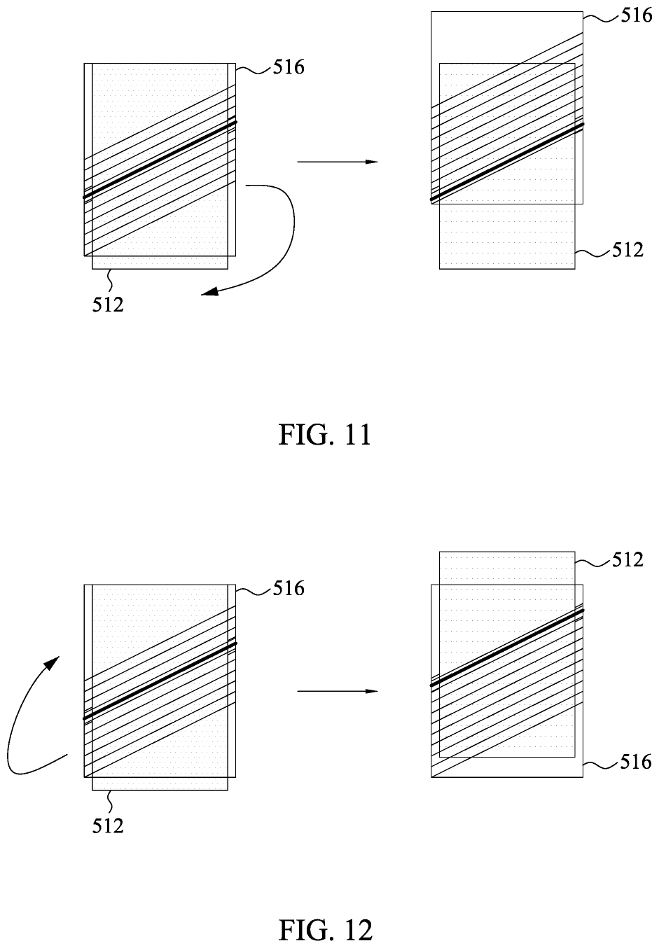

FIGS. 11 and 12 are a side views of one hollow structure 502 in the adaptable collimator 500 according to one or more embodiments in the present disclosure.

Referring to FIGS. 9-12, the hollow structure 502 includes an inner hollow member 512 and an outer hollow member 516. In some embodiments, to adjust the length of the hollow structure 502, the inner hollow member 512 is configured to rotate in the outer hollow member 516. As the inner hollow member 512 is rotated in a first direction, the length of the hollow structure 502 becomes shorter. Similarly, as the inner hollow member 512 is rotated in a second direction, the length of the hollow structure 502 becomes longer.

In the illustrated embodiment shown in FIGS. 9-12, the outer hollow member 516 includes an internal threads (helical groove) 518, and the inner hollow member 512 includes a protrusion 514 (e.g., partial helical protrusion) that fits to the internal threads (helical groove) 518 during the rotating movement.

In some embodiments, the length of the hollow structure 502 is adjusted by rotating the inner hollow member 512 using a motor (not shown) based on the configuration control signal from the controller 300.

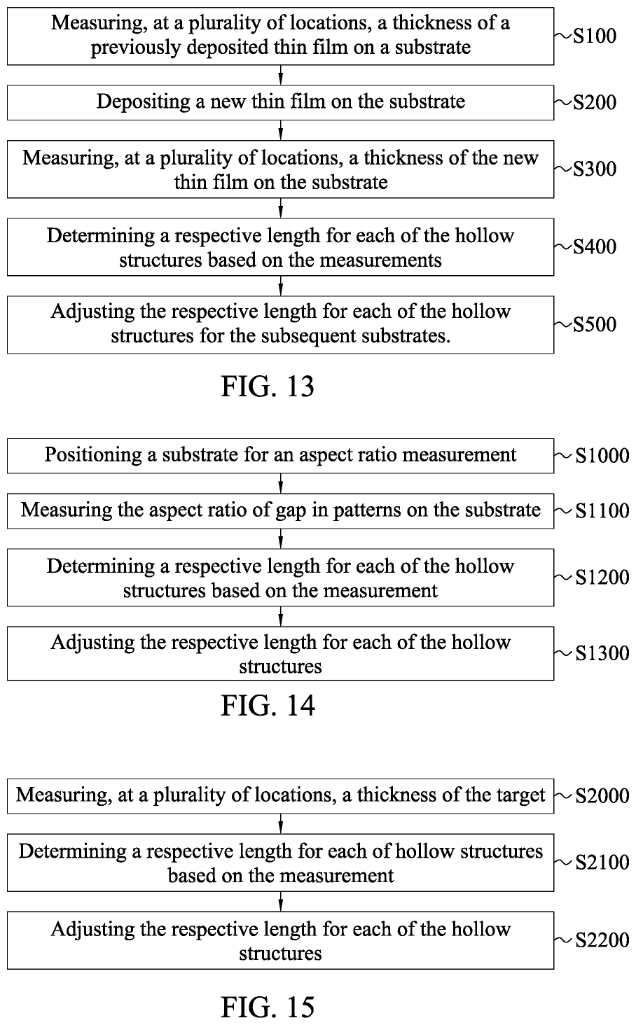

FIG. 13 is a flow chart illustrating a method of increasing uniformity of a thin film on the subsequent substrates according to various embodiments.

Referring to FIG. 13, the method of increasing uniformity of the thin film on the subsequent substrates includes: step S100 of measuring, at a plurality of locations, a thickness of the thin film 904 that was deposited on the substrate 902 prior to the substrate process chamber 200; step S200 of depositing a thin film 904 on the substrate 902; step S300 of measuring, at the plurality of locations, a thickness of the thin film 904 on the substrate 902; and step S400 of determining the respective length for each of the hollow structures 502 based on the measurement taken before and after the substrate process chamber 200; and step S500 of adjusting the respective length for each of the hollow structures 502 for the subsequent substrates.

Step S100 of measuring, at the plurality of locations, the thickness of the thin film that was deposited on the substrate 902 prior to the substrate process chamber 200 includes a step of measuring the thin film that was previously deposited on the substrate 902. As discussed above, in some embodiments, the thickness measurement is collected at the cool down chamber 600. In some embodiments, the thickness measurement of the thin film that was previously deposited on the substrate 902 is transmitted to the controller 300.

Step S200 of depositing the thin film 904 on the substrate 902 includes a step of depositing the thin film 904 on the substrate 902.

Step S300 of measuring, at the plurality of locations, the thickness of the thin film 904 on the substrate 902 includes a step of measuring the thin film 904 on the substrate 902. As discussed above, in some embodiments, the thickness measurement is collected at the cool down chamber 600. In some embodiments, the cool down chamber 600 can be the same chamber used to measure the thin film that was deposited previously. In some embodiments, the cool down chamber 600 can be different chamber. In some embodiments, the thickness measurement of the thin film 904 deposited on the substrate 902 at the substrate process chamber 200 is transmitted to the controller 300.

Step S400 of determining the respective length for each of the hollow structures 502 based on the measurement taken before and after the substrate process chamber 200 includes a step of determining an appropriate length for each of the hollow structures 502 based on the thickness measurements taken before and after the deposition. Based on the comparison, the uniformity of the thin film 904 deposited on the substrate 902 (or thickness of the thin film 904 at the plurality of locations on the substrate 902) can be determined. Based on the measurements, the respective length for each of the hollow structures 502 is determined. As discussed above, in some embodiments, the controller 300 determines the respective length for each of the hollow structures 502 using one or more artificial intelligence techniques.

Step S500 of adjusting each length of the hollow structures 502 for the subsequent substrates includes a step of adjusting each of the hollow structures 502 according to the determined appropriate lengths. In some embodiments, the controller 300 transmits the configuration control signal to the adaptable collimator 500 to adjust the length for each of the hollow structures 502. In some embodiments, step S100 is omitted and step S300 is used to measure the thin film 904 deposited on the substrate 902. Accordingly, in some embodiments, the Step S400 of determining the respective length for each of the hollow structures 502 based on the thickness measurements taken after the deposition. Based on the measurement taken after deposition, the uniformity of the thin film 904 deposited on the substrate 902 (or thickness of the thin film 904 at the plurality of locations on the substrate 902) can be determined.

FIG. 14 is a flow chart illustrating a method of adjusting each length of the hollow structures 502 based on the aspect ratio of a gap (in the pattern) on the substrate 902.

Referring to FIG. 14, the method of adjusting each length of the hollow structures 502 includes: step S1000 of positioning the substrate 902 for the aspect ratio measurement; step S1100 of measuring the aspect ratio of gap (in the pattern) on the substrate 902; step S1200 of determining the respective length for each of the hollow structures 502 based on the measurement; and step S1300 of adjusting each length of the hollow structures 502 for the substrate 902.

Step S1000 of positioning the substrate 902 for the aspect ratio measurement includes a step of positioning the substrate 902 for the aspect ratio measurement (e.g., measurement position or lower positon). In some embodiments, as discussed above, the shutter disk 900 with the aspect ratio measurement device 622 is positioned above the substrate 902 for the aspect ratio measurement.

Step S1100 of measuring the aspect ratio of gap in the pattern on the substrate 902 includes a step of measuring the aspect ratio of gap in the pattern on the substrate 902. As discussed above, in some embodiments, the shutter disk 900 includes the aspect ratio measurement device 622 having one or more image analysis devices 624 that can measure the aspect ratio of the gap in the pattern on the substrate 902. In some embodiments, the aspect ratio measurement measured by the aspect ratio measurement device 622 is transmitted to the controller 300.

Step S1200 of determining the respective length for each of the hollow structures 502 based on the measurement includes a step of determining appropriate length for each of the hollow structures 502 based on the measured aspect ratio for the gap (gap structure) on the substrate 902. As discussed above, the controller 300 determines the appropriate length for each of the hollow structures 502 using one or more artificial intelligence techniques.

Step S1300 of adjusting each length of the hollow structures 502 for the substrate 902 includes a step of adjusting each length of the hollow structures 502 according to the determined appropriate lengths. In some embodiments, the controller 300 transmits the configuration control signal to the adaptable collimator 500 to adjust the length for each of the hollow structures 502 to the appropriate length.

FIG. 15 is flow chart illustrating a method of adjusting each of the hollow structures 502 based on target erosion profile measurement.

Referring to FIG. 15, the method of adjusting each of the hollow structures 502 includes: step S2000 of measuring, at a plurality of locations, a thickness of the target 204; step S2100 of determining the respective length for each of the hollow structure 502 based on the measurement; and step S2200 of adjusting the respective length for each of the hollow structures 502.

Step S2000 of measuring, at the plurality of locations, the thickness of the target 204 includes a step of measuring the erosion profile of the target 204. As discussed above, in some embodiments, ultrasonic sensors 404 located above the target 204 are used to measure the thickness of the target 204 at the plurality of locations using at least one non-destructive testing technique. In some embodiments, the erosion profile measured by the ultrasonic sensors 404 is transmitted to the controller 300.

Step S2100 of determining the respective length for each of the hollow structures 502 based on the measurement includes a step of determining an appropriate length for each of the hollow structures 502 based on the measured erosion profile. As discussed above, in some embodiments, the controller 300 determines the respective length for each of the hollow structures 502 using one or more artificial intelligence techniques.

Step S2200 of adjusting each length of the hollow structures 502 for the substrate 902 includes a step of adjusting each length of the hollow structures 502 according to the determined appropriate lengths. In some embodiments, the controller 300 transmits the configuration control signal to the adaptable collimator 500 to adjust the length for each of the hollow structures 502 to the appropriate length.

Utilizing the adaptable collimator 500 will produce a substantial cost savings by its capability of extending the lifetime of the target, and increasing production yield by reducing fabrication issues such as void, overhang, and abnormal uniformity.

According to one or more embodiments of present disclosure, a method of depositing a material from a target onto a substrate in a substrate process chamber includes depositing a film of the material on the substrate. The thin film is deposited on the substrate using any suitable methods such as sputtering. The method includes measuring, at a plurality of locations, a thickness of the film on the substrate. The method further includes determining a length for each of hollow structures in a collimator based on the measuring at the plurality of locations.

According to one or more embodiments of the present disclosure, a deposition system is provided that is capable of controlling an amount of a target material deposited on a substrate and/or the direction of the target material that is deposited on the substrate. The deposition system in accordance with the present disclosure includes a substrate process chamber. The deposition system includes a substrate pedestal in the substrate process chamber, the substrate pedestal configured to support a substrate, a target enclosing the substrate process chamber, and a collimator having a plurality of hollow structures disposed between the target and the substrate, wherein a length of at least one of the plurality of hollow structures is adjustable.

According to one or more embodiments of the present disclosure, a deposition system includes an artificial intelligence controller, a substrate process chamber, a target enclosing the substrate process chamber, and a collimator having a plurality of hollow structures disposed between the target and the substrate, wherein the artificial intelligence controller is configured to control a length of at least one of the plurality of hollow structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of depositing a material from a target onto a substrate in a substrate process chamber, comprising:
depositing a film of the material on the substrate;
measuring, at a plurality of locations, a thickness of the film on the substrate, the plurality of locations including a first location; and
determining a respective length for each of a plurality of hollow structures in a collimator based on the measuring at the plurality of locations, the determining including determining a first length of a first hollow structure of the hollow structures that is corresponding to the first location.

2. The method according to claim 1, wherein when a first thickness of the film at the first location is greater than a predetermined thickness, the first length of the first hollow structure is increased to the determined length.

3. The method according to claim 1, wherein when a first thickness of the film at the first location is less than a predetermined thickness, the first length of the first hollow structure is decreased to the determined length.

4. The method according to claim 1, further comprising determining an average thickness of the film deposited on the substrate based on the measuring at the plurality of locations.

5. The method according to claim 4, wherein when a first thickness of the film at the first location is greater than the average thickness of the film, the first length of the first hollow structure is increased to the determined length.

6. The method according to claim 4, wherein when a first thickness of the film at the first location is less than the average thickness of the film, the first length of the first hollow structure is decreased to the determined length.

7. The method according to claim 1, wherein the first hollow structure includes a first hollow member and a second hollow member, the first hollow member and the second hollow member overlapped with each other.

8. The method according to claim 1, wherein the first hollow structure includes a first hollow member and a second hollow member, the first hollow member and the second hollow member partially overlapped with each other.

9. The method according to claim 8, wherein the first hollow member includes an internal helical groove, and wherein the second hollow member includes a helical protrusion that fits to the internal helical groove.

10. The method according to claim 1, wherein each of the plurality of hollow structures is configured to extend and retract independently in a linear direction.

11. A deposition system, comprising:
a substrate process chamber;
a substrate pedestal in the substrate process chamber, the substrate pedestal configured to support a substrate;
a target enclosing the substrate process chamber; and
a collimator having a plurality of hollow structures disposed between the target and the substrate, wherein a length of at least one of the plurality of hollow structures is adjustable.

12. The deposition system according to claim 11, wherein the at least one of the plurality of hollow structures includes a first hollow member and a second hollow member, the first hollow member and the second hollow member overlapped with each other.

13. The deposition system according to claim 11, wherein the at least one of the plurality of hollow structures includes a first hollow member and a second hollow member, the first hollow member and the second hollow member at least partially overlapped with each other.

14. The deposition system according to claim 11, wherein the at least one of the plurality of hollow structures includes a first hollow member and a second hollow member, and wherein the first hollow member includes an internal helical groove, and wherein the second hollow member includes a helical protrusion that fits to the internal helical groove.

15. The deposition system according to claim 14, wherein a rotational movement of the second hollow member moves the second hollow member in a linear direction.

16. The deposition system according to claim 15, further comprising a controller that controls the rotational movement of the second hollow member based on at least one of target profile measurement data, size of gap in a pattern on the substrate, or thin film thickness measurement.

17. The deposition system according to claim 11 further comprising a controller, in operation, determines the length based on at least one artificial intelligence method.

18. A deposition system, comprising:
an artificial intelligence controller;
a substrate process chamber;
a target enclosing the substrate process chamber; and
a collimator having a plurality of hollow structures disposed between the target and a substrate, wherein the artificial intelligence controller is configured to control a length of at least one of the plurality of hollow structures.

19. The deposition system according to claim 18, wherein the artificial intelligence controller includes a memory that stores training data and a collimator configuration database.

20. The deposition system according to claim 19, wherein the training data includes an initial set of data points for training the artificial intelligence controller for controlling the length of at least one of the plurality of hollow structures.
